(19) United States
(12) Patent Application Publication
(10) Pub. No.: US 2025/0292844 A1
(43) Pub. Date: Sep. 18, 2025

(54) Validating Uninitialized Usage-Based-Disturbance Data

(71) Applicant: Micron Technology, Inc., Boise, ID (US)

(72) Inventors: Yang Lu, Boise, ID (US); Kang-Yong Kim, Boise, ID (US)

(73) Assignee: Micron Technology, Inc., Boise, ID (US)

(21) Appl. No.: 19/042,563

(22) Filed: Jan. 31, 2025

Related U.S. Application Data
(60) Provisional application No. 63/566,753, filed on Mar. 18, 2024.

(51) Int. Cl. G11C 16/34; G11C 16/20; G11C 29/52

(52) U.S. Cl. CPC G11C 16/3418; G11C 16/20; G11C 29/52

(57) ABSTRACT

Apparatuses and techniques for validating uninitialized usage-based-disturbance data are described. In an example aspect, a memory device stores usage-based-disturbance data within a subset of memory cells of multiple rows of a memory array. Instead of initializing the usage-based-disturbance data using a dedicated initialization procedure or instead of temporarily disabling usage-based disturbance mitigation until the data is initialized, the described techniques validate uninitialized usage-based-disturbance data such that the effects of usage-based disturbance can be mitigated during a startup procedure. Usage-based-disturbance data that fails to be validated is initialized. Usage-based-disturbance data that is validated can be acted upon by performing a mitigation procedure. In this sense, initialization is performed in real time while usage-based-disturbance mitigation techniques may be employed.

### CROSS-REFERENCE TO RELATED APPLICATION(S)

This application claims the benefit of U.S. Provisional Patent Application Ser. No. 63/566,753 filed on Mar. 18, 2024, the disclosure of which is incorporated by reference herein in its entirety.

### BACKGROUND

Computers, smartphones, and other electronic devices rely on processors and memories. A processor executes code based on data to run applications and provide features to a user. The processor obtains the code and the data from a memory. The memory in an electronic device can include volatile memory (e.g., random-access memory (RAM)) and non-volatile memory (e.g., flash memory). Like the capabilities of a processor, the capabilities of a memory can impact the performance of an electronic device. This performance impact can increase as processors are developed that execute code faster and as applications operate on increasingly larger data sets that require ever-larger memories.

### BRIEF DESCRIPTION OF THE DRAWINGS

Apparatuses of and techniques for validating uninitialized usage-based-disturbance data are described with reference to the following drawings. The same numbers are used throughout the drawings to reference like features and components:

FIG. 1 illustrates example apparatuses that can implement aspects of validating uninitialized usage-based-disturbance data;

FIG. 2 illustrates an example computing system that can implement aspects of validating uninitialized usage-based-disturbance data;

FIG. 3 illustrates example data stored within rows of a memory array;

FIG. 4 illustrates an example memory device in which aspects of validating uninitialized usage-based-disturbance data may be implemented;

FIG. 5 illustrates an example arrangement of validation circuits on a die;

FIG. 6 illustrates example implementations of a validation circuit and a validation control circuit for implementing aspects of validating uninitialized usage-based-disturbance data;

FIG. 7 illustrates an example implementation of a validation circuit capable of validating uninitialized usage-based-disturbance data;

FIG. 8 illustrates an operational flow diagram for performing aspects of validating uninitialized usage-based-disturbance data; and

FIG. 9 illustrates an example method for implementing aspects of validating uninitialized usage-based-disturbance data.

### DETAILED DESCRIPTION

### Overview

Processors and memory work in tandem to provide features to users of computers and other electronic devices. As processors and memory operate more quickly together in a complementary manner, an electronic device can provide enhanced features, such as high-resolution graphics and artificial intelligence (AI) analysis. Some applications, such as those for financial services, medical devices, and advanced driver assistance systems (ADAS), can also demand more-reliable memories. These applications use increasingly reliable memories to limit errors in financial transactions, medical decisions, and object identification. However, in some implementations, more-reliable memories can sacrifice bit densities, power efficiency, and simplicity.

To meet the demands for physically smaller memories, memory devices can be designed with higher chip densities. Increasing chip density, however, can increase the electromagnetic coupling (e.g., capacitive coupling) between adjacent or proximate rows of memory cells due, at least in part, to a shrinking distance between these rows. With this undesired coupling, activation (or charging) of a first row of memory cells can sometimes negatively impact a second nearby row of memory cells. In particular, activation of the first row can generate interference, or crosstalk, that causes the second row to experience a voltage fluctuation. In some instances, this voltage fluctuation can cause a state (or value) of a memory cell in the second row to be incorrectly determined by a sense amplifier. Consider an example in which a state of a memory cell in the second row is a “1,” In this example, the voltage fluctuation can cause a sense amplifier to incorrectly determine the state of the memory cell to be a “0” instead of a “1.” Left unchecked, this interference can lead to memory errors or data loss within the memory device.

In some circumstances, a particular row of memory cells is activated repeatedly in an unintentional or intentional (sometimes malicious) manner. Consider, for instance, that memory cells in an R^{th} row are subjected to repeated activation, which causes one or more memory cells in an adjacent row (e.g., within an R+1 row, an R+2 row, an R−1 row, and/or an R−2 row) to change states. This effect is referred to as usage-based disturbance. The occurrence of usage-based disturbance can lead to the corruption or changing of contents within the affected row of memory.

Some memory devices utilize circuits that can detect usage-based disturbance and mitigate its effects. To monitor for usage-based disturbance, a memory device can store an activation count within each row of a memory array. The activation count keeps track of a quantity of accesses or activations of the corresponding memory row. If the activation count meets or exceeds a threshold, then proximate rows, including one or more adjacent rows, may be at increased risk for data corruption due to the repeated activations of the accessed row and the usage-based disturbance effect. To manage this risk to the affected rows, the memory device can refresh the proximate rows.

Data that is stored within the memory array and referenced for usage-based-disturbance mitigation can be in an unknown state when the memory device is powered on. At start up, for instance, the activation counts for different rows can appear to have random values. Some of these values may be above or close to a threshold for triggering actions that mitigate usage-based disturbance effects. It can be challenging to evaluate the data and determine whether it is initialized or uninitialized. Furthermore, a significant amount of time can pass between a time that the memory device is powered on and a time that the memory device is operational (e.g., is able to perform normal read and/or write operations). During this time, the memory device may execute a startup procedure, which can include an initialization procedure, a calibration procedure, a training procedure, a reset procedure, a refresh procedure, or some combination thereof. It can be advantageous to have the memory device mitigate usage-based disturbance during the startup procedure. However, prior to the initialization of the data that is referenced for usage-based-disturbance mitigation, uninitialized values of the data can cause the memory device to perform unnecessary mitigation operations or cause unnecessary alert conditions. Both of these events can divert resources from the startup procedure. It can therefore be challenging to perform usage-based-disturbance mitigation while data that is referenced for usage-based-disturbance mitigation is uninitialized.

Some techniques may attempt to solve this problem by performing a dedicated initialization procedure during the startup procedure to initialize the usage-based-disturbance data. This dedicated initialization procedure, however, can take a significant amount of time (e.g., approximately ten milliseconds or more depending on the size of the memory array). Also, the initialization procedure can prevent the memory device from performing other operations. Consequently, performing a dedicated initialization procedure can extend the time it takes for the memory device to complete the startup procedure and become fully and safely operational. This delay may be unsatisfactory for some host devices and/or users.

Other techniques may temporarily disable the mitigation of usage-based disturbance effects until the memory device has refreshed the memory array. Prior to the memory array being initialized, however, the memory device is vulnerable to usage-based disturbance. As densities of memory devices increase, it becomes even more important to enable usage-based disturbance mitigation as soon as possible. As such, there is a general need to allow usage-based disturbance mitigation to be performed prior to the usage-based-disturbance data being initialized and with little or any impact on the startup procedure.

To address these and other issues regarding usage-based disturbance, this document describes techniques for validating uninitialized usage-based-disturbance data. In an example aspect, a memory device stores usage-based-disturbance data within a subset of memory cells of multiple rows of a memory array. Instead of initializing the usage-based-disturbance data using a dedicated initialization procedure or instead of temporarily disabling usage-based disturbance mitigation until the data is initialized, the described techniques validate uninitialized usage-based-disturbance data such that the effects of usage-based disturbance can be mitigated during a startup procedure. Usage-based-disturbance data that fails to be validated is initialized. Usage-based-disturbance data that is validated can be acted upon by performing a mitigation procedure. In this sense, initialization is performed in real time while usage-based-disturbance mitigation techniques may be employed.

### Example Operating Environments

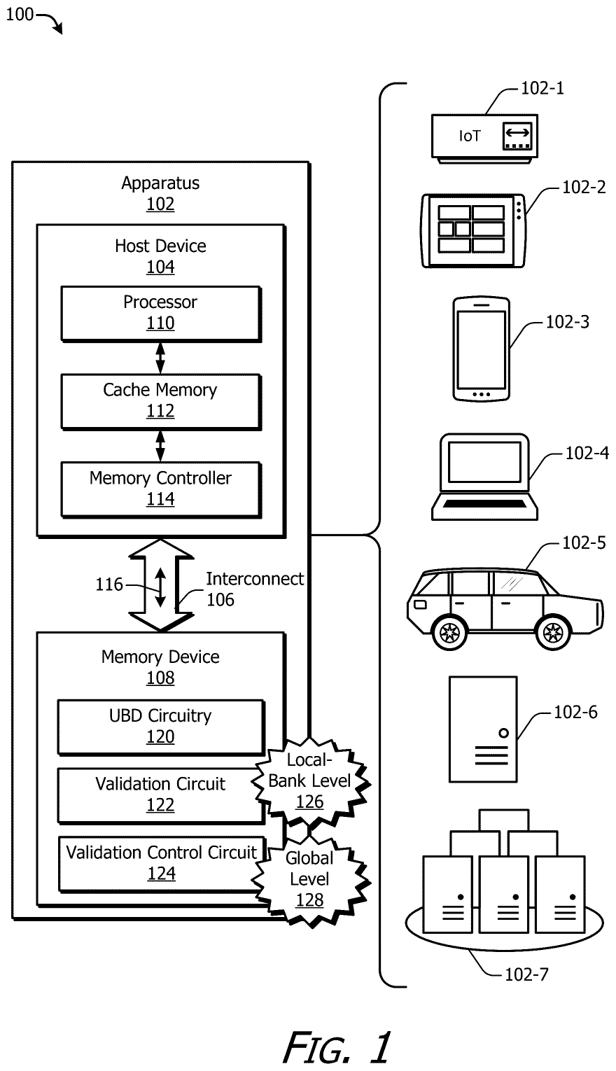

FIG. 1 illustrates, at 100 generally, an example operating environment including an apparatus 102 that can implement aspects of controlling usage-based disturbance mitigation. The apparatus 102 can include various types of electronic devices, including an internet-of-things (IoT) device 102-1, tablet device 102-2, smartphone 102-3, notebook computer 102-4, passenger vehicle 102-5, server computer 102-6, and server cluster 102-7 that may be part of cloud computing infrastructure, a data center, or a portion thereof (e.g., a printed circuit board (PCB)). Other examples of the apparatus 102 include a wearable device (e.g., a smartwatch or intelligent glasses), entertainment device (e.g., a set-top box, video dongle, smart television, a gaming device), desktop computer, motherboard, server blade, consumer appliance, vehicle, drone, industrial equipment, security device, sensor, or the electronic components thereof. Each type of apparatus can include one or more components to provide computing functionalities or features.

In example implementations, the apparatus 102 can include at least one host device 104, at least one interconnect 106, and at least one memory device 108. The host device 104 can include at least one processor 110, at least one cache memory 112, and a memory controller 114. The memory device 108, which can also be realized with a memory module, can include, for example, a dynamic random-access memory (DRAM) die or module (e.g., Low-Power Double Data Rate synchronous DRAM (LPDDR SDRAM)). The DRAM die or module can include a three-dimensional (3D) stacked DRAM device, which may be a high-bandwidth memory (HBM) device or a hybrid memory cube (HMC) device. The memory device 108 can operate as a main memory for the apparatus 102. Although not illustrated, the apparatus 102 can also include storage memory. The storage memory can include, for example, a storage-class memory device (e.g., a flash memory, hard disk drive, solid-state drive, phase-change memory (PCM), or memory employing 3D XPoint™).

The processor 110 is operatively coupled to the cache memory 112, which is operatively coupled to the memory controller 114. The processor 110 is also coupled, directly or indirectly, to the memory controller 114. The host device 104 may include other components to form, for instance, a system-on-a-chip (SoC). The processor 110 may include a general-purpose processor, central processing unit, graphics processing unit (GPU), neural network engine or accelerator, application-specific integrated circuit (ASIC), field-programmable gate array (FPGA) integrated circuit (IC), or communications processor (e.g., a modem or baseband processor).

In operation, the memory controller 114 can provide a high-level or logical interface between the processor 110 and at least one memory (e.g., an external memory). The memory controller 114 may be realized with any of a variety of suitable memory controllers (e.g., a double-data-rate (DDR) memory controller that can process requests for data stored on the memory device 108). Although not shown, the host device 104 may include a physical interface (PHY) that transfers data between the memory controller 114 and the memory device 108 through the interconnect 106. For example, the physical interface may be an interface that is compatible with a DDR PHY Interface (DFI) Group interface protocol. The memory controller 114 can, for example, receive memory requests from the processor 110 and provide the memory requests to external memory with appropriate formatting, timing, and reordering. The memory controller 114 can also forward to the processor 110 responses to the memory requests received from external memory.

The host device 104 is operatively coupled, via the interconnect 106, to the memory device 108. In some examples, the memory device 108 is connected to the host device 104 via the interconnect 106 with an intervening buffer or cache. The memory device 108 may operatively couple to storage memory (not shown). The host device 104 can also be coupled, directly or indirectly via the interconnect 106, to the memory device 108 and the storage memory. The interconnect 106 and other interconnects (not illustrated in FIG. 1) can transfer data between two or more components of the apparatus 102. Examples of the interconnect 106 include a bus (e.g., a unidirectional or bidirectional bus), switching fabric, or one or more wires that carry voltage or current signals. The interconnect 106 can propagate one or more communications 116 between the host device 104 and the memory device 108. For example, the host device 104 may transmit a memory request to the memory device 108 over the interconnect 106. Also, the memory device 108 may transmit a corresponding memory response to the host device 104 over the interconnect 106.

The illustrated components of the apparatus 102 represent an example architecture with a hierarchical memory system. A hierarchical memory system may include memories at different levels, with each level having memory with a different speed or capacity. As illustrated, the cache memory 112 logically couples the processor 110 to the memory device 108. In the illustrated implementation, the cache memory 112 is at a higher level than the memory device 108. A storage memory, in turn, can be at a lower level than the main memory (e.g., the memory device 108). Memory at lower hierarchical levels may have a decreased speed but increased capacity relative to memory at higher hierarchical levels.

The apparatus 102 can be implemented in various manners with more, fewer, or different components. For example, the host device 104 may include multiple cache memories (e.g., including multiple levels of cache memory) or no cache memory. In other implementations, the host device 104 may omit the processor 110 or the memory controller 114. A memory (e.g., the memory device 108) may have an “internal” or “local” cache memory. As another example, the apparatus 102 may include cache memory between the interconnect 106 and the memory device 108. Computer engineers can also include any of the illustrated components in distributed or shared memory systems.

Computer engineers may implement the host device 104 and the various memories in multiple manners. In some cases, the host device 104 and the memory device 108 can be disposed on, or physically supported by, a printed circuit board (e.g., a rigid or flexible motherboard). The host device 104 and the memory device 108 may additionally be integrated together on an integrated circuit or fabricated on separate integrated circuits and packaged together. The memory device 108 may also be coupled to multiple host devices 104 via one or more interconnects 106 and may respond to memory requests from two or more host devices 104. Each host device 104 may include a respective memory controller 114, or the multiple host devices 104 may share a memory controller 114. This document describes with reference to FIG. 1 an example computing system architecture having at least one host device 104 coupled to a memory device 108.

Two or more memory components (e.g., modules, dies, banks, or bank groups) can share the electrical paths or couplings of the interconnect 106. The interconnect 106 can include at least one command-and-address bus (CA bus) and at least one data bus (DQ bus). The command-and-address bus can transmit addresses and commands from the memory controller 114 of the host device 104 to the memory device 108, which may exclude propagation of data. The data bus can propagate data between the memory controller 114 and the memory device 108. The memory device 108 may also be implemented as any suitable memory including, but not limited to, DRAM, SDRAM, three-dimensional (3D) stacked DRAM, DDR memory, or LPDDR memory (e.g., LPDDR DRAM or LPDDR SDRAM).

The memory device 108 can form at least part of the main memory of the apparatus 102. The memory device 108 may, however, form at least part of a cache memory, a storage memory, or a system-on-chip of the apparatus 102. The memory device 108 includes at least one instance of usage-based disturbance circuitry 120 (UBD circuitry 120), at least one validation circuit 122, and at least one validation control circuit 124. The usage-based-disturbance circuitry 120, the validation circuit 122, and the validation control circuit 124 can each be implemented using software, firmware, hardware, fixed logic circuitry, or some combinations thereof. The validation circuit 122 can be integrated within the usage-based-disturbance circuitry 120 or can be considered separate from the usage-based-disturbance circuitry 120.

The usage-based disturbance circuitry 120 mitigates usage-based disturbance for one or more banks associated with the memory device 108. The usage-based disturbance circuitry 120 can also include at least one counter circuit for detecting conditions associated with usage-based disturbance, at least one queue for managing refresh operations for mitigating the usage-based disturbance, and/or at least one error-correction-code (ECC) circuit for detecting and/or correcting bit errors associated with usage-based disturbance.

One aspect of usage-based disturbance mitigation involves keeping track of how often a row is activated or accessed since a last refresh. In particular, the usage-based disturbance circuitry 120 performs an array counter update (ACU) procedure using the counter circuit to update an activation count associated with an activated row. During the array counter update procedure, the usage-based disturbance circuitry 120 reads the activation count that is stored within the activated row, increments the activation count, and writes the updated activation count to the activated row. By maintaining the activation count, the usage-based disturbance circuitry 120 can determine when to perform a refresh operation to reduce the risk of usage-based disturbance. For example, when the activation count meets or exceeds a threshold, the usage-based disturbance circuitry 120 can perform a mitigation procedure that refreshes one or more rows that are near the activated row to mitigate the usage-based disturbance.

The validation circuit 122 controls the use of uninitialized data for usage-based-disturbance mitigation. Data that is uninitialized has an unknown state. In some cases, values associated with the uninitialized data can appear random. The validation circuit 122 detects conditions associated with invalid values of the data and prevents the usage-based-disturbance circuitry 120 from performing unnecessary mitigation steps in these circumstances. In this way, the validation circuit 122 conserves resources of the memory device 108. Furthermore, the validation circuit 122 can cause the usage-based-disturbance circuitry 120 to initialize data that has the invalid values. The initialization process sets the data to a known state. This real time initialization can further assist with performing usage-based-disturbance mitigation while the memory device executes a startup procedure and before the memory device 108 completes a refresh procedure. With the validation techniques employed by the validation circuit 122, the memory device 108 can support usage-based disturbance mitigation without significantly increasing a time it takes to perform the startup procedure.

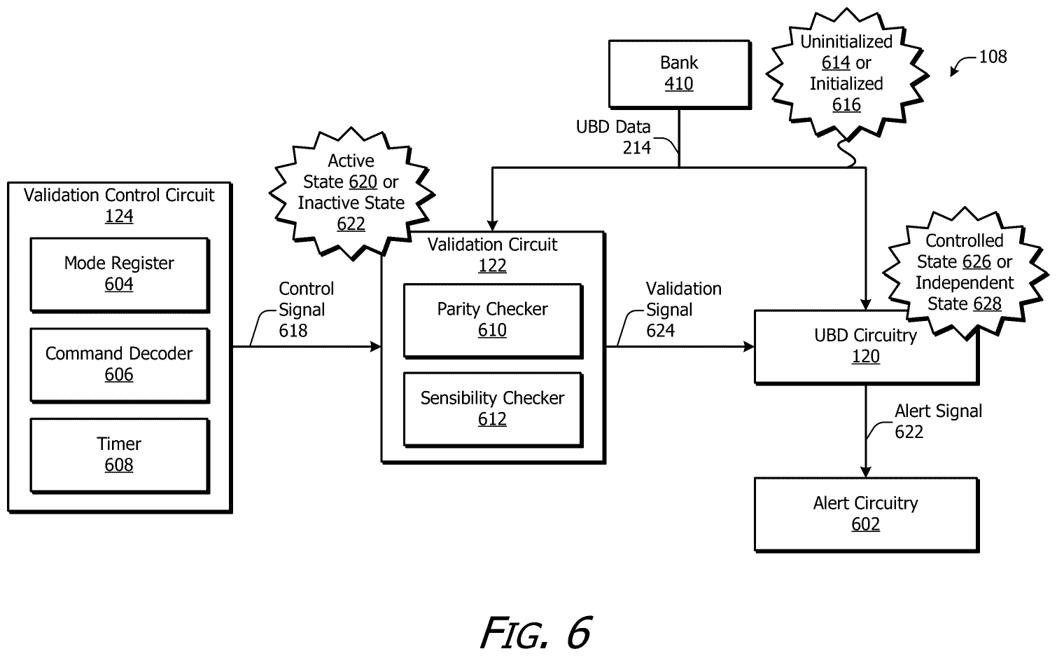

The validation control circuit 124 controls an operation of the validation circuit 122. In particular, the validation control circuit 124 can cause the validation circuit 122 to be in an active state (e.g., an enabled state) or an inactive state (e.g., a disabled state), which are further described with respect to FIG. 6. In general, the validation control circuit 124 activates the validation control circuit 124 during the startup procedure and deactivates the validation circuit 122 once a condition is met that indicates the data utilized for usage-based-disturbance mitigation is initialized.

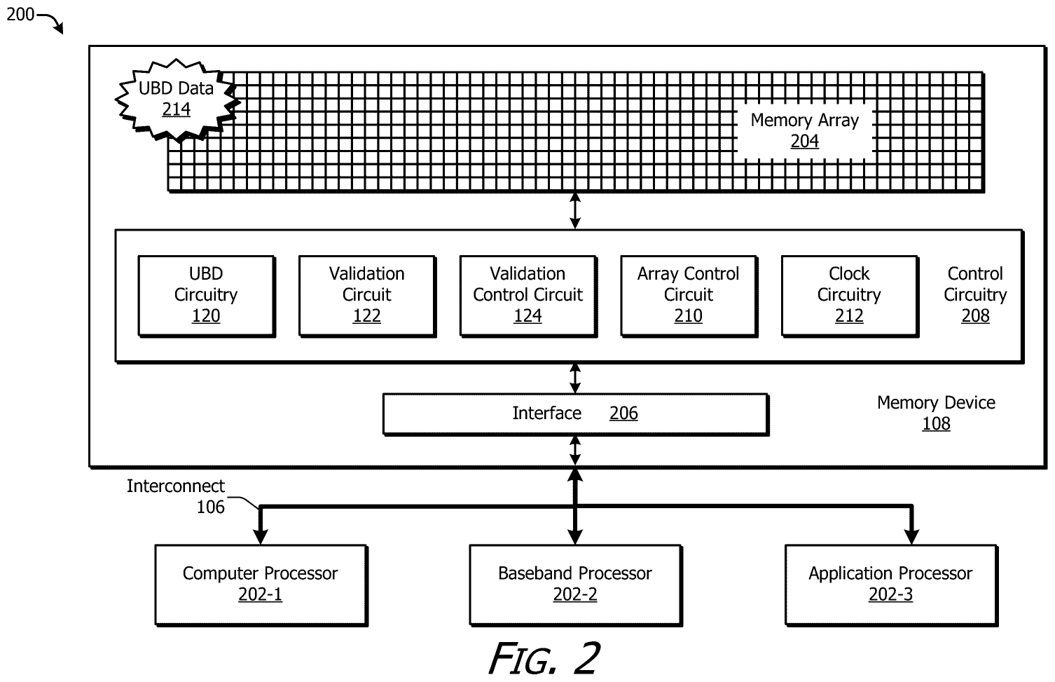

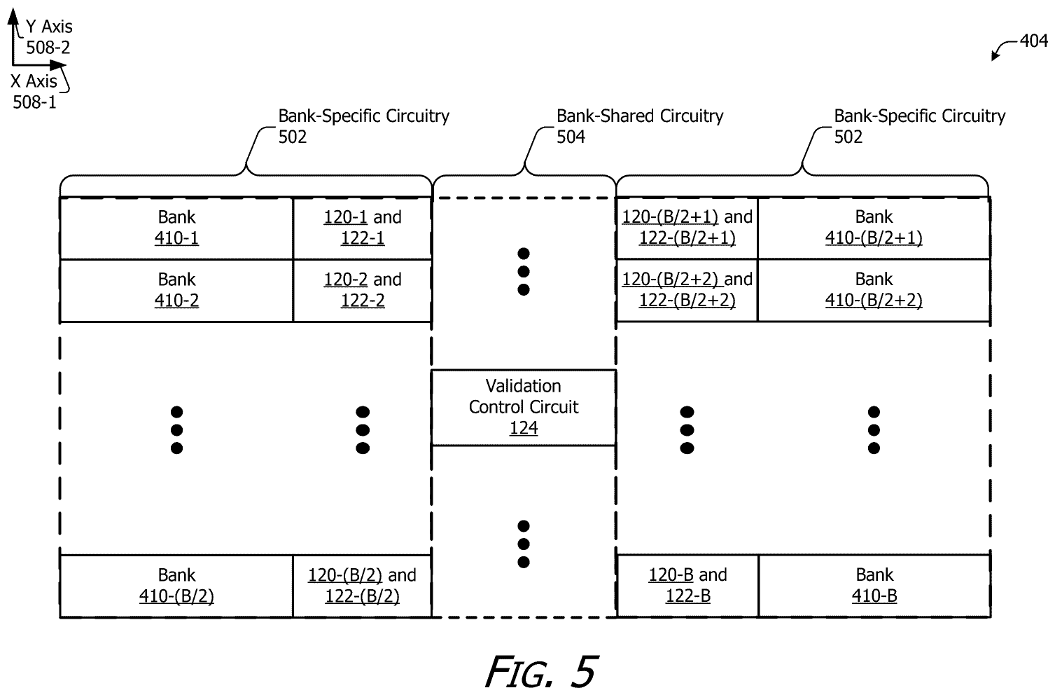

In example implementations, the validation circuit 122 is implemented at a local-bank level 126. This means that each validation circuit 122 validates data that is stored within a corresponding bank of the memory device 108. The validation control circuit 124, in contrast to the validation circuit 122, is implemented at a global level 128. This means that one instance of the validation control circuit 124 can service two or more validation circuits 122 that are implemented at the local-bank level 126. The local-bank level 126 implementation of the validation circuit 122 and the global level 128 implementation of the validation control circuit are further described with respect to FIG. 5. Other components of the memory device 108 are further described with respect to FIG. 2.

FIG. 2 illustrates an example computing system 200 that can implement aspects of validating uninitialized usage-based-disturbance data. In some implementations, the computing system 200 includes at least one memory device 108, at least one interconnect 106, and at least one processor 202. The memory device 108 can include, or be associated with, at least one memory array 204, at least one interface 206, and control circuitry 208 (or periphery circuitry) operatively coupled to the memory array 204. The memory array 204 can include an array of memory cells, including but not limited to memory cells of DRAM, SDRAM, three-dimensional (3D) stacked DRAM, DDR memory, LPDDR SDRAM, and so forth. The memory array 204 and the control circuitry 208 may be components on a single semiconductor die or on separate semiconductor dies. The memory array 204 or the control circuitry 208 may also be distributed across multiple dies. This control circuitry 208 may manage traffic on a bus that is separate from the interconnect 106.

The control circuitry 208 can include various components that the memory device 108 can use to perform various operations. These operations can include communicating with other devices, managing memory performance, performing refresh operations (e.g., self-refresh operations or auto-refresh operations), and performing memory read or write operations. In the depicted configuration, the control circuitry 208 includes the usage-based disturbance circuitry 120, the validation circuit 122, the validation control circuit 124, at least one array control circuit 210, and at least one instance of clock circuitry 212. In some implementations, the usage-based-disturbance circuitry 120, the validation circuit 122, and the validation control circuit 124 are part of the control circuitry 208, as shown in FIG. 2. In other implementations, the usage-based-disturbance circuitry 120, the validation circuit 122, the validation control circuit 124, or some combination thereof are considered separate from the control circuitry 208.

The array control circuit 210 can include circuitry that provides command decoding, address decoding, input/output functions, amplification circuitry, power supply management, power control modes, and other functions. The clock circuitry 212 can synchronize various memory components with one or more external clock signals provided over the interconnect 106, including a command-and-address clock or a data clock. The clock circuitry 212 can also use an internal clock signal to synchronize memory components and may provide timer functionality.

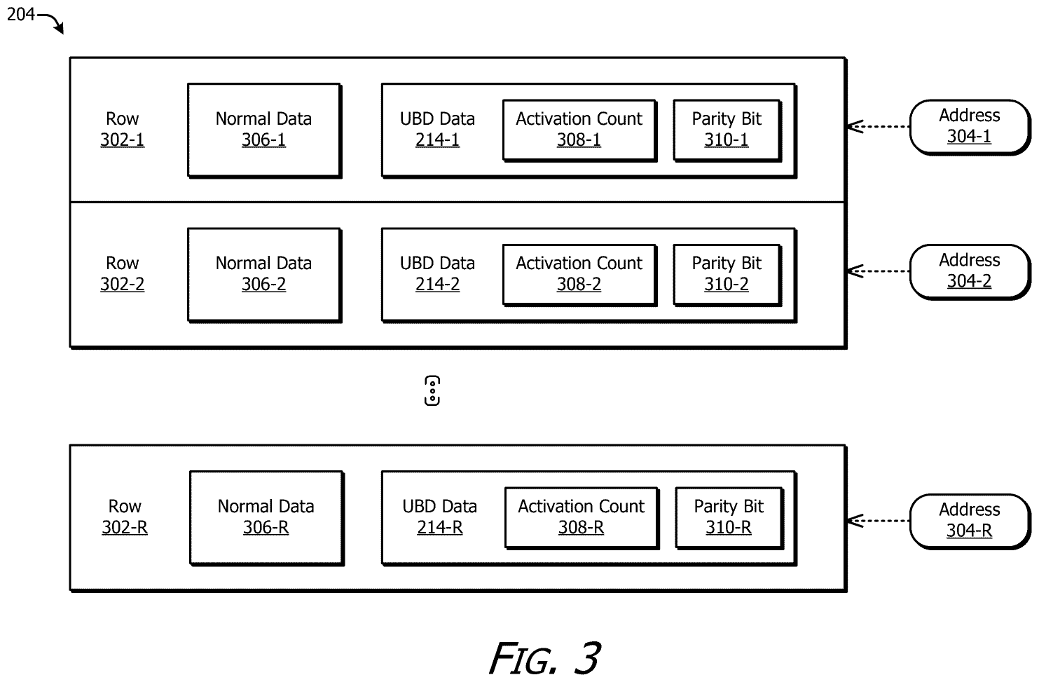

The usage-based disturbance circuitry 120 and the validation circuit 122 can be coupled to a set of memory cells within the memory array 204 that store usage-based-disturbance data 214 (UBD data 214). The usage-based-disturbance data 214 can include information such as an activation count, which represents a quantity of times one or more rows within the memory array 204 have been activated (or accessed) by the memory device 108. In example implementations, each row of the memory array 204 includes a subset of memory cells that stores the usage-based-disturbance data 214 associated with that row, as further described with respect to FIG. 3.

The interface 206 can couple the control circuitry 208 or the memory array 204 directly or indirectly to the interconnect 106. In some implementations, the usage-based disturbance circuitry 120, the validation circuit 122, the validation control circuit 124, the array control circuit 210, and the clock circuitry 212 can be part of a single component (e.g., the control circuitry 208). In other implementations, one or more of the usage-based disturbance circuitry 120, the validation circuit 122, the validation control circuit 124, the array control circuit 210, or the clock circuitry 212 may be implemented as separate components, which can be provided on a single semiconductor die or disposed across multiple semiconductor dies. These components may individually or jointly couple to the interconnect 106 via the interface 206.

The interconnect 106 may use one or more of a variety of interconnects that communicatively couple together various components and enable commands, addresses, or other information and data to be transferred between two or more components (e.g., between the memory device 108 and the processor 202). Although the interconnect 106 is illustrated with a single line in FIG. 2, the interconnect 106 may include at least one bus, at least one switching fabric, one or more wires or traces that carry voltage or current signals, at least one switch, one or more buffers, and so forth. Further, the interconnect 106 may be separated into at least a command-and-address bus and a data bus.

In some aspects, the memory device 108 may be a “separate” component relative to the host device 104 (of FIG. 1) or any of the processors 202. The separate components can include a printed circuit board, memory card, memory stick, and memory module (e.g., a single in-line memory module (SIMM) or dual in-line memory module (DIMM)). Thus, separate physical components may be located together within the same housing of an electronic device or may be distributed over a server rack, a data center, and so forth. Alternatively, the memory device 108 may be integrated with other physical components, including the host device 104 or the processor 202, by being combined on a printed circuit board or in a single package or a system-on-chip.

As shown in FIG. 2, the processors 202 may include a computer processor 202-1, a baseband processor 202-2, and an application processor 202-3, coupled to the memory device 108 through the interconnect 106. The processors 202 may include or form a part of a central processing unit, graphics processing unit, system-on-chip, application-specific integrated circuit, or field-programmable gate array. In some cases, a single processor can comprise multiple processing resources, each dedicated to different functions (e.g., modem management, applications, graphics, central processing). In some implementations, the baseband processor 202-2 may include or be coupled to a modem (not illustrated in FIG. 2) and referred to as a modem processor. The modem or the baseband processor 202-2 may be coupled wirelessly to a network via, for example, cellular, Wi-Fi®, Bluetooth®, near field, or another technology or protocol for wireless communication.

In some implementations, the processors 202 may be connected directly to the memory device 108 (e.g., via the interconnect 106). In other implementations, one or more of the processors 202 may be indirectly connected to the memory device 108 (e.g., over a network connection or through one or more other devices). The memory array 204 is further described with respect to FIG. 3.

FIG. 3 illustrates example data stored within rows of the memory array 204. The memory array 204 includes multiple rows 302 of memory cells. For example, the memory array 204 depicted in FIG. 3 includes rows 302-1, 302-2 . . . 302-R, where R represents a positive integer. Each row 302 is associated with an address 304 (e.g., a row address, a memory row address, or a memory address). For example, the first row 302-1 has a first address 304-1, the second row 302-2 has a second address 304-2, and an R^{th} row 302-R has an R^{th} address 304-R.

Each of the rows 302 can store normal data 306 within a first subset of the memory cells associated with that row 302. The normal data 306 represents data that is read from or written to the memory device 108 during normal memory operations (e.g., during normal read or write operations). The normal data 306, for example, can include data that is transmitted by the memory controller 114 and is written to one or more rows 302 of the memory array 204.

In addition to the normal data 306, each of the rows 302 can store usage-based-disturbance data 214 within a second subset of the memory cells associated with that row 302. The usage-based-disturbance data 214 includes information that enables the usage-based disturbance circuitry 120 to mitigate usage-based disturbance. In an example implementation, the usage-based-disturbance data 214 includes an activation count 308.

In this example, the first row 302-1 stores first normal data 306-1 within a first subset of memory cells of the first row 302-1 and stores first usage-based-disturbance data 214-1 within a second subset of memory cells of the first row 302-1. The first usage-based-disturbance data 214-1 includes a first activation count 308-1, which represents a quantity of times the first row 302-1 has been activated since a last refresh. As another example, the second row 302-2 stores second normal data 306-2 within a first subset of memory cells within the second row 302-2 and stores second usage-based-disturbance data 214-2 within a second subset of memory cells within the second row 302-2. The second usage-based-disturbance data 214-2 includes a second activation count 308-2, which represents a quantity of times the second row 302-2 has been activated since a last refresh. Additionally, the R^{th} row 302-R stores R^{th} normal data 306-R within a first subset of memory cells within the R^{th} row 302-R and stores R^{th} usage-based-disturbance data 214-R within a second subset of memory cells within the R^{th} row 302-R. The R^{th} usage-based-disturbance data 214-R includes an R^{th} activation count 308-R, which represents a quantity of times the R^{th} row 302-R has been activated since a last refresh.

The usage-based-disturbance data 214 also includes information or is formatted (e.g., coded) in such a way as to support error detection. In this example, the usage-based-disturbance data 214 includes a parity bit 310 to enable detection of an uninitialized activation count 308 using a parity check. For instance, the usage-based-disturbance data 214-1, 214-2, and 214-R respectively includes parity bits 310-1, 310-2, and 310-R. Other implementations are also possible in which the usage-based-disturbance data 214 is coded in a manner that supports any of the error detection tests described above, such as the error-correcting-code check. Although the techniques for validating uninitialized usage-based-disturbance data 214 are described with respect to the activation count 308, these techniques can generally be applied to any type of information that is represented by the usage-based-disturbance data 214 and can utilize any type of error detection technique associated with this data.

### Example Techniques and Hardware

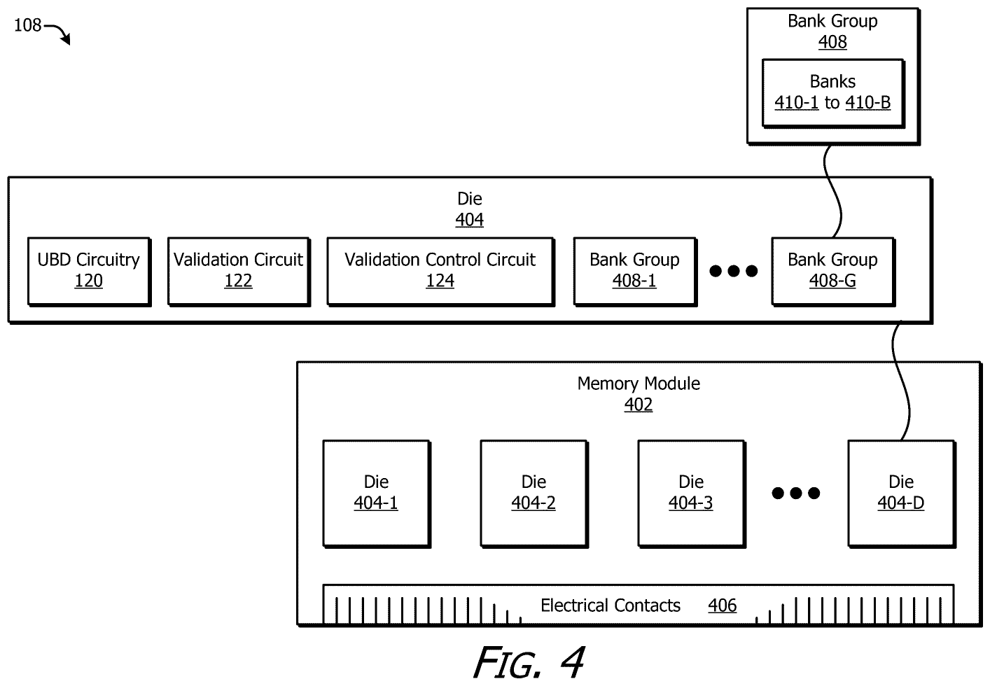

FIG. 4 illustrates an example memory device 108 in which aspects of validating uninitialized usage-based-disturbance data 214 can be implemented. The memory device 108 includes a memory module 402, which can include multiple dies 404. As illustrated, the memory module 402 includes a first die 404-1, a second die 404-2, a third die 404-3, and a D^{th} die 404-D, with D representing a positive integer. The memory module 402 can be a SIMM or a DIMM. As another example, the memory module 402 can interface with other components via a bus interconnect (e.g., a Peripheral Component Interconnect Express (PCIe®) bus). The memory device 108 illustrated in FIGS. 1 and 2 can correspond, for example, to multiple dies (or dice) 404-1 through 404-D, or a memory module 402 with two or more dies 404. As shown, the memory module 402 can include one or more electrical contacts 406 (e.g., pins) to interface the memory module 402 to other components.

The memory module 402 can be implemented in various manners. For example, the memory module 402 may include a printed circuit board, and the multiple dies 404-1 through 404-D may be mounted or otherwise attached to the printed circuit board. The dies 404 (e.g., memory dies) may be arranged in a line or along two or more dimensions (e.g., forming a grid or array). The dies 404 may have a similar size or may have different sizes. Each die 404 may be similar to another die 404 or different in size, shape, data capacity, or control circuitries. The dies 404 may also be positioned on a single side or on multiple sides of the memory module 402.

One or more of the dies 404-1 to 404-D include the usage-based disturbance circuitry 120, validation circuit 122, the validation control circuit 124, and bank groups 408-1 to 408-G, with G representing a positive integer. Each bank group 408 includes at least two banks 410, such as banks 410-1 to 410-B, with B representing a positive integer. In some implementations, the die 404 includes multiple instances of the usage-based disturbance circuitry 120, which mitigate usage-based disturbance across at least one of the banks 410. The die 404 also includes multiple instances of the validation circuit 122, which validates usage-based-disturbance data 214 stored within at least one of the banks 410. For example, multiple instances of the usage-based disturbance circuitry 120 can respectively mitigate usage-based disturbance across the bank groups 408-1 to 408-G. Also, multiple instances of the validation circuit 122 can respectively validate usage-based-disturbance data 214 stored across the bank groups 408-1 to 408-G.

In other implementations, multiple instances of the usage-based disturbance circuitry 120 can respectively mitigate usage-based disturbance for respective banks 410. Also, multiple instances of the validation circuit 122 can respectively validate usage-based-disturbance data 214 that is stored within respective banks 410. In this case, each usage-based disturbance circuitry 120 mitigates usage-based disturbance for a single bank 410 within one of the bank groups 408-1 to 408-B. Also, each validation circuit 122 validates usage-based-disturbance data for a single bank 410 within one of the bank groups 408-1 to 408-B.

In yet other example implementations, each usage-based disturbance circuitry 120 mitigates usage-based disturbance for a subset of the banks 410 associated with one of the bank groups 408-1 to 408-G, where the subset of the banks 410 includes at least two banks 410. Also, each validation circuit 122 validates usage-based-disturbance data 214 stored within a subset of the banks 410 associated with one of the bank groups 408-1 to 408-G.

Various implementations of the validation control circuit 124 are also possible. In a first example, the die 404 includes a single validation control circuit 124 that is coupled to the one or more instances of the validation circuit 122. In a second example, the die 404 includes multiple validation control circuits 124 that are coupled to respective sets of one or more validation circuits 122. The relationship between the banks 410-1 to 410-B, the usage-based-disturbance circuitry 120, and the validation circuit 122 are further described with respect to FIG. 5.

FIG. 5 illustrates an example arrangement of multiple instances of the usage-based-disturbance circuitry 120 and multiple validation circuits 122 on a die 404. The die 404 includes bank-specific circuitry 502 and bank-shared circuitry 504. Bank-specific circuitry 502 includes components that are associated with a particular bank 410. For example, the bank-specific circuitry 502 includes the banks 410-1, 410-2 . . . 410-(B/2), 410-(B/2+1), 410-(B/2+2) . . . 410-B, the usage-based-disturbance circuitry 120-1, 120-2 . . . 120-(B/2), 120-(B/2+1), 120-(B/2+2) . . . 120-B, and the validation circuits 122-1, 122-2 . . . 122-(B/2), 122-(B/2+1), 122-(B/2+2) . . . 122-B. The usage-based-disturbance circuitry 120-1 to 120-B and the validation circuits 122-1 to 122-B are respectively coupled to the banks 410-1 to 410-B. In some cases, subsets of the banks 410-1 to 410-B are associated with different bank groups 408. In an example implementation, the die 404 includes 32 banks 410 (e.g., B equals 32). The 32 banks 410 form eight bank groups 408 (e.g., G equals 8), with each bank group 408 including four of the banks 410. In other cases, the banks 410-1 to 410-B are associated with a single bank group 408.

Each validation circuit 122 can enable usage-based-disturbance mitigation techniques to be performed using uninitialized usage-based-disturbance data 214 stored within the corresponding bank 410. For example, the first validation circuit 122-1 can provide validation for the usage-based-disturbance data 214 stored within the rows 302 of the first bank 410-1. Likewise, the validation circuit 1242-2 can provide validation for the usage-based-disturbance data 214 stored within the rows 302 of the second bank 410-2.

The bank-shared circuitry 504 includes components that are associated with multiple banks 410. These components perform operations associated with multiple banks 410. Example components of the bank-shared circuitry 504 include the validation control circuit 124. In this example, the usage-based disturbance circuitry 120 and the validation circuits 122 are shown as part of the bank-specific circuitry 502. Other implementations are also possible in which the usage-based disturbance circuitry 120 and the validation circuit 122 are implemented as part of the bank-shared circuitry 504.

On the die 404, the bank-specific circuitry 502 is positioned on two opposite sides of the bank-shared circuitry 504. Explained another way, the bank-shared circuitry 504 can be centrally positioned on the die 404. As such, the validation control circuit 124 can be positioned closer to a center of the die 404 compared to the edges of the die 404. Positioning the bank-shared circuitry 504 in the center enables routing between the bank-shared circuitry 504 and the bank-specific circuitry 502 to be simplified.

Consider a first axis 508-1 (e.g., X axis 508-1) and a second axis 508-2 (e.g., Y axis 508-2), which is perpendicular to the first axis 508-1. In FIG. 5, the first axis 508-1 is depicted as a “horizontal” axis, and the second axis 508-2 is depicted as a “vertical” axis. Components of the bank-shared circuitry 504 are distributed across the second axis 508-2. A first set of the banks (e.g., banks 410-1 to 410-B/2) are arranged along the second axis 508-2 on a “left” side of the bank-shared circuitry 504, and a second set of the banks (e.g., banks 410-(B/2+1) to 410-B) are arranged along the second axis 508-2 on a “right” side of the bank-shared circuitry 504. The usage-based-disturbance circuitry 120-1 to 120-B and the validation circuits 122-1 to 122-B are positioned between the corresponding banks 410-1 to 410-B and the bank-shared circuitry 504. By positioning the validation control circuit 124 in a central location between the validation circuits 122-1 to 122-B, it can be easier to route signals between the validation control circuit 124 and the validation circuits 122-1 to 122-B. Operations of the validation circuits 122 and the validation control circuit 124 are further described with respect to FIG. 6.

FIG. 6 illustrates example implementations of the validation circuit 122 and the validation control circuit 124. In the depicted configuration, the validation circuit 122 is coupled between the validation control circuit 124 and the usage-based-disturbance circuitry 120. The validation circuit 122 and the usage-based-disturbance circuitry 120 are coupled to one or more banks 410 (or more generally the memory array 204). The usage-based-disturbance circuitry 120 is also coupled to at least one instance of alert circuitry 602. The alert circuitry 602 can be implemented at the global level 128 and can be considered part of the control circuitry 208.

The validation control circuit 124 controls an operation of the validation circuit 122. Example implementations of the validation control circuit 124 can include at least one mode register 604, at least one command decoder 606, and/or at least one timer 608. Each of these components can cause the validation circuit 122 to be in an appropriate state depending on whether the usage-based-disturbance data 214 is considered to be uninitialized or initialized.

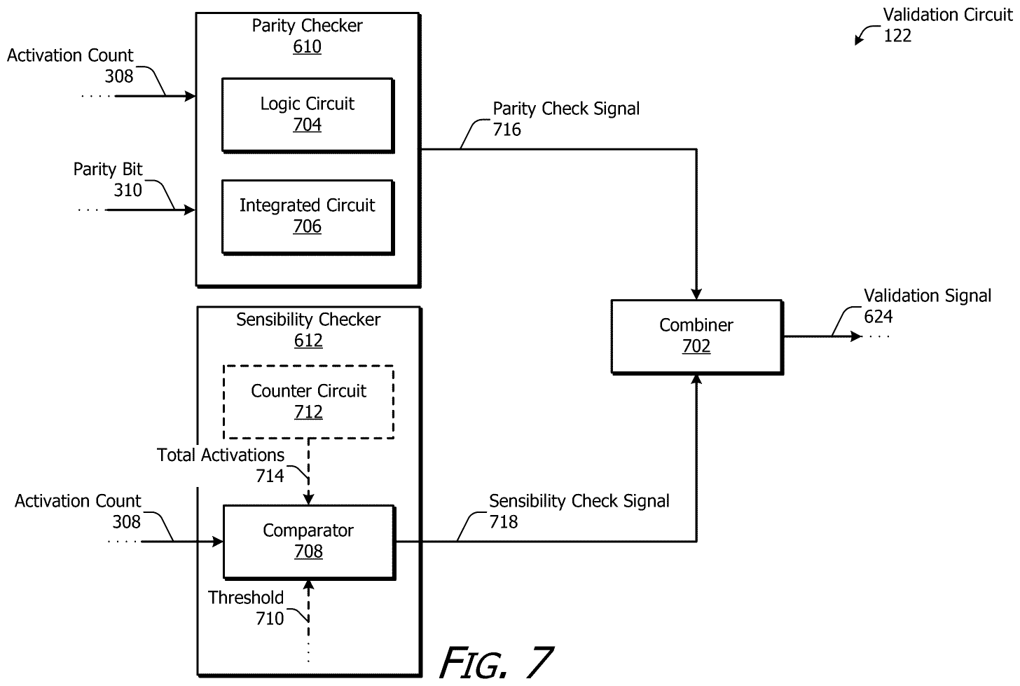

The validation circuit 122 performs a validation procedure to determine whether the usage-based-disturbance data 214 is valid or invalid. This validation procedure is particularly useful for enabling mitigation of usage-based disturbance while the usage-based-disturbance data 214 (or portions thereof) are uninitialized. In example implementations, the validation circuit 122 can be implemented using at least one parity checker 610, at least one sensibility checker 612, or some combination thereof. The parity checker 610 evaluates a parity of the usage-based-disturbance data 214 as part of the validation procedure. The sensibility checker 612 evaluates a feasibility of a value of the usage-based-disturbance data 214 as part of the validation procedure. Operations of the parity checker 610 and/or the sensibility checker 612 are further described with respect to FIG. 7.

Generally speaking, the validation procedure can include a variety of different tests to determine a validity of the usage-based-disturbance data 214. Example tests can include a parity check (as described with respect to the parity checker 610), a sensitivity check (as described with respect to the sensibility checker 612), an error-correcting-code check, a checksum check, a cyclic redundancy check, another type of error detection procedure, or some combination thereof. The type of test and/or the utilization of multiple tests can be chosen such that the memory device 108 can realize a particular level of accuracy regarding invalidating uninitialized data. The validation circuit 122 can control an operation of the usage-based-disturbance circuitry 120 based on the result of the validation procedure.

The usage-based-disturbance circuitry 120 performs one or more operations associated with mitigating usage-based disturbance within the bank 410. An example operation can include reading the usage-based-disturbance data 214 from the bank 410, updating the usage-based-disturbance data 214, and writing the updated usage-based-disturbance data 214 back to the bank 410. In particular, the operation can include the array counter update procedure, as described above. In some situations, the usage-based-disturbance circuitry 120 can detect an occurrence of an alert condition. In this case, the usage-based-disturbance circuitry 120 can trigger the alert circuitry 602 to generate an alert.

The alert circuitry 602 enables the memory device 108 to inform the memory controller 114 of the alert condition detected by the usage-based-disturbance circuitry 120. In some implementations, information provided by the alert circuitry 602 can cause the memory controller 114 to initiate a repair process (e.g., a soft post-package repair (sPPR) or a hard post-package repair (hPPR). In a first example implementation, the alert circuitry 602 generates a signal, such as a reliability, availability, and serviceability (RAS) event signal or another type of alert signal, which can be provided to the memory controller 114 to indicate occurrence of the alert condition. In a second example implementation, the alert circuitry 602 includes at least one mode register with at least one operand that can be set by the usage-based-disturbance circuitry 120 to indicate the occurrence of the alert condition.

The bank 410 stores the usage-based-disturbance data 214, which can be uninitialized 614 or initialized 616. When the usage-based-disturbance data 214 is uninitialized 614, this means that the usage-based-disturbance data 214 is in an unknown state. In other words, a value of the activation count 308 and/or the parity bit 310 may or may not be appropriate or have meaning. In some cases, the values of the activation counts 308 can appear random. Generally speaking, the usage-based-disturbance data 214 is uninitialized at startup and prior to the memory device 108 completing a refresh procedure that refreshes all the rows 302 in the memory array 204. While the usage-based-disturbance data 214 is uninitialized 614, some values of the usage-based-disturbance data 214 may unintentionally trigger the mitigation of usage-based disturbance. These actions can require additional resources, which can delay completion of the startup procedure. To reduce a risk of the uninitialized 614 usage-based-disturbance data 214 wasting resources, the validation circuit 122 first validates the usage-based-disturbance data 214 prior to the usage-based-disturbance circuitry 120 performing an operation that uses the usage-based-disturbance data 214.

When the usage-based-disturbance data 214 is initialized 616, the usage-based-disturbance data 214 can be considered to be in a known state. In other words, a value of the activation count 308 and/or the parity bit 310 is appropriate and has meaning. Generally speaking, the usage-based-disturbance data 214 is initialized prior to the memory device 108 performing normal operations (e.g., normal read/write operations) or prior to completion of the startup procedure. While the usage-based-disturbance data 214 is initialized 616, the usage-based-disturbance circuitry 120 can operate as normal using the usage-based-disturbance data 214. In other words, an operation that uses the usage-based-disturbance data 214 can be performed without prior validation of the usage-based-disturbance data 214.

Another state of the usage-based-disturbance data 214 is also possible in which the usage-based-disturbance data 214 is partially initialized. This means that a first portion of the usage-based-disturbance data 214 is initialized 616 while a second portion of the usage-based-disturbance data 214 is uninitialized 614. Explained another way, the usage-based-disturbance data 214 can be partially initialized if the usage-based-disturbance data 214 stored within a first set of rows 302 were previously initialized while the usage-based-disturbance data 214 stored within a second set of rows 302 have yet to be initialized. This can occur in the middle of the refresh procedure or during the startup procedure as the validation circuit 122 causes the usage-based-disturbance circuitry 120 to initialized portions of the usage-based-disturbance data 214 that were determined to be invalid.

During operation, the validation control circuit 124 generates a control signal 618, which causes the validation circuit 122 to be in an active state 620 or an inactive state 622. More specifically, the validation control circuit 124 generates the control signal 618 to cause the validation circuit 122 to be in the active state 620 based on the memory device 108 performing a startup procedure. Once the validation control circuit 124 detects occurrence of a condition that is indicative of the usage-based-disturbance data 214 having been initialized, the validation control circuit 124 generates the control signal 618 in a manner that causes the validation circuit 122 to be in the inactive state 622. Example conditions are further described below.

A first example condition can include the memory device 108 setting a value of the mode register 604 to indicate completion of the refresh procedure. A second example condition can include the command decoder 606 receiving a particular command from the memory controller 114. A third example condition can include the timer 608 expiring. In this case, a duration of the timer 608 is indicative of a time it takes for the memory device 108 to complete initialization the usage-based-disturbance data 214 since a beginning of the startup procedure.

The validation circuit 122 generates a validation signal 624, which can control an operation of the usage-based-disturbance circuitry 120. While in the active state 620, the validation circuit 122 validates the usage-based-disturbance data 214 prior to the usage-based-disturbance circuitry 120 using the usage-based-disturbance data 214. In this case, the validation signal 624 indicates the result of the validation procedure (e.g., whether the usage-based-disturbance data 214 is determined to be valid or invalid). While in the inactive state 622, the validation circuit 122 can generate the validation signal 624 to indicate to the usage-based-disturbance circuitry 120 that the validation circuit 122 is in the inactive state 622. Other implementations are also possible in which the validation control circuit 124 passes the control signal 618 to the usage-based-disturbance circuitry 120. In this case, the control signal 618 can indicate whether the validation circuit 122 is in the active state 620 or the inactive state 622. To summarize, the validation circuit 122 performs the validation procedure while in the active state 620 and does not perform the validation procedure while in the inactive state 622.

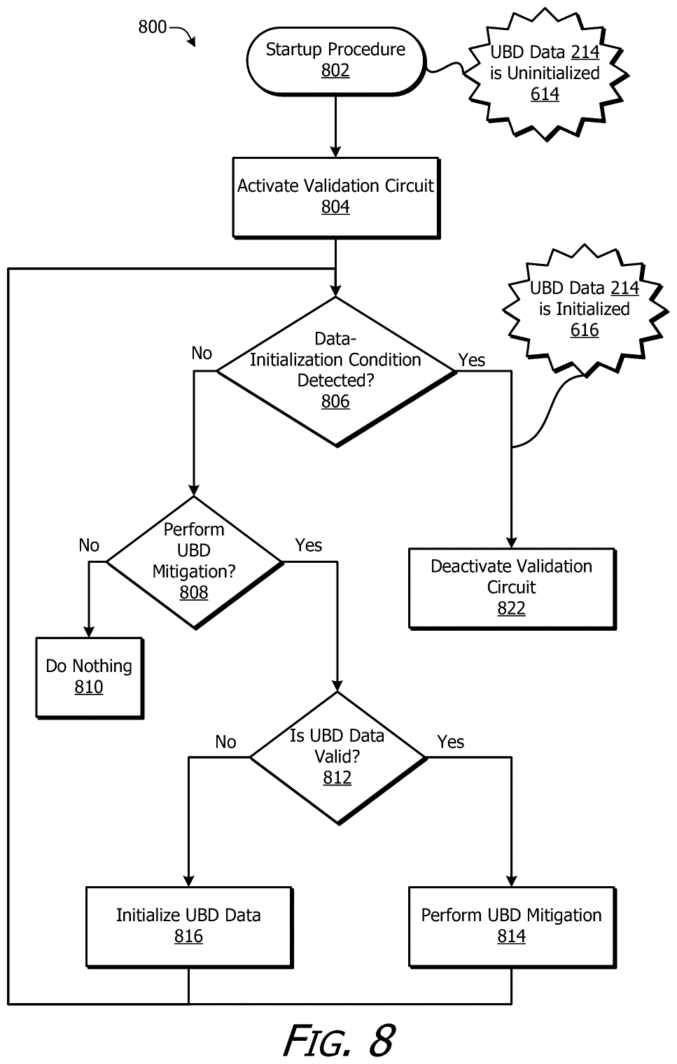

The usage-based-disturbance circuitry 120 can perform different operations depending on the information provided via the validation signal 624. Example operations are further described with respect to FIG. 8. While the validation circuit 122 is in the active state 620, the usage-based-disturbance circuitry 120 operates in accordance with a controlled state 626. While in the controlled state 626, the usage-based-disturbance circuitry 120 can perform an operation associated with mitigating usage-based disturbance (e.g., perform the array counter update procedure) if the validation signal 624 indicates that the usage-based-disturbance data 214 is valid. Otherwise, the usage-based-disturbance circuitry 120 can initialize the usage-based-disturbance data 214 if the validation signal 624 indicates that the usage-based-disturbance data 214 is invalid. This initialization enables portions of the usage-based-disturbance data 214 to be sporadically initialized in real time during the startup procedure.

While the usage-based-disturbance circuitry 120 is in the controlled state 626, the usage-based-disturbance circuitry 120 does not activate or utilize the alert circuitry 602. In this manner, the usage-based-disturbance circuitry 120 can prevent alerts from occurring while the memory device 108 is performing the startup procedure.

While the validation circuit 122 is in the inactive state 622, the usage-based-disturbance circuitry 120 operates in accordance with an independent state 628. This means that the usage-based-disturbance circuitry 120 can perform an operation associated with mitigating usage-based disturbance (e.g., perform the array counter update procedure) without the validation circuit 122 validating the usage-based-disturbance data 214. In other words, the usage-based-disturbance circuitry 120 operates independent of the validation circuit 122 when the validation circuit 122 is in the inactive state 622.

While the usage-based-disturbance circuitry 120 is in the independent state 628, the usage-based-disturbance circuitry 120 can activate or utilize the alert circuitry 602 when an alert condition is detected. In an example situation, the alert condition causes the memory device 108 to execute an alert “back-off” (ABO) procedure. During the alert back-off procedure, the memory device 108 pauses normal operations for a recovery period during which refresh management (RFM) commands or other functions may be performed in the memory device 108 to mitigate usage-based disturbance. During this recovery period, the victim rows are refreshed. An example implementation of the validation circuit 122 is further described with respect to FIG. 7.

FIG. 7 illustrates an example implementation of the validation circuit 122. In the depicted configuration, the validation circuit 122 includes the parity checker 610, the sensibility checker 612, and a combiner 702. Other implementations are also possible in which the validation circuit 122 includes the parity checker 610 and does not include the sensibility checker 612 and the combiner 702. Still other implementations of the validation circuit 122 can include the sensibility checker 612 and does not include the parity checker 610 and the combiner 702. In this example, the parity checker 610 and the sensibility checker 612 evaluate the activation count 308 to determine whether or not the usage-based-disturbance data 214 is valid.

The parity checker 610 performs the validation procedure by evaluating a parity of the activation count 308. In particular, the parity checker 610 calculates a parity of the activation count 308 and compares this to the parity bit 310. If the parity bit 310 represents the parity of the activation count 308, the parity checker 610 determines that the usage-based-disturbance data 214 is valid. Alternatively, if the parity bit 310 does not represent the parity of the activation count 308, the parity checker 610 determines that the usage-based-disturbance data 214 is invalid. The parity checker 610 can be implemented using at least one logic circuit 704 or at least one integrated circuit 706. The logic circuit 704 can include a network of gates, such as exclusive OR gates (XOR or EOR or EXOR gates) or exclusive NOR gates (XNOR, ENOR, EXNOR, NXOR gates). The logic circuit 704 or the integrated circuit 706 can be implemented as an even parity checker or an odd parity checker as appropriate.

The sensibility checker 612 performs the validation procedure by evaluating a feasibility of a value of the activation count 308. In particular, the sensibility checker 612 compares the activation count 308 to a particular value. If the activation count 308 is less than the particular value, the sensibility checker 612 determines that the usage-based-disturbance data 214 is valid. Alternatively, if the activation count 308 is greater than the particular value, the sensibility checker 612 determines that the usage-based-disturbance data 214 is invalid.

The sensibility checker 612 can be implemented using at least one comparator 708. In a first example implementation, the comparator 708 compares the activation count 308 to a threshold 710. The threshold 710 can be a fixed value that doesn't change based on the operation of the memory device 108. Other implementations are also possible in which the threshold 710 can be adjusted by the memory device 108 and/or the memory controller 114. In an example implementation, the threshold 710 can represent a fraction of another threshold that is used during the array counter update procedure to trigger a refresh operation. In general, the threshold 710 indicates a value that is unlikely to be reached during the startup procedure if the usage-based-disturbance data had been initialized 616.

In a second example implementation, the sensibility checker 612 includes a counter circuit 712, which counts a quantity of activations that have occurred within the bank 410 since initialization of the startup procedure. In this case, the comparator 708 compares the activation count 308 to total activations 714 determined by the counter circuit 712.

The combiner 702 combines the results generated by the parity checker 610 and the sensibility checker 612 to generate the validation signal 624. In an example implementation, the combiner 702 is implemented using an AND gate or a multiplexer. Other implementations of the combiner 702 are also possible.

During operation, the parity checker 610 generates a parity check signal 716 and the sensibility checker 612 generates a sensibility check signal 718. The parity check signal 716 and the sensibility check signal 718 each indicate whether or not the corresponding test determined the usage-based-disturbance data 214 to be valid or invalid. The combiner 702 generates the validation signal 624 based on a combination of the parity check signal 716 and the sensibility check signal 718. In this example, the validation signal 624 indicates that the usage-based-disturbance data 214 is valid if both the parity check signal 716 and the sensibility check signal 718 indicate that the usage-based-disturbance data 214 is valid. Otherwise, the validation signal 624 indicates that the usage-based-disturbance data 214 is invalid if at least one of the parity check signal 716 or the sensibility check signal 718 indicate that the usage-based-disturbance data 214 is invalid. The validation circuit 122 can perform this validation procedure during the startup procedure 802, as further described with respect to FIG. 8.

FIG. 8 illustrates an example operational flow diagram 800 for performing aspects of validating uninitialized usage-based-disturbance data 214. At 802, the memory device 108 is powered up and initiates a startup procedure. As part of the startup procedure 802, the memory device 108 can perform operations such as an initialization procedure, a calibration procedure, a training procedure, a reset procedure, a refresh procedure, or some combination thereof. At the beginning of the startup procedure 802, the usage-based-disturbance data 214 is uninitialized 614.

At 804, the validation circuit 122 is activated. For example, the memory device 108 or the control circuitry 208 can configure the validation control circuit 124 to activate the validation circuit 122 (e.g., to cause the validation circuit 122 to be in the active state 620). This can include setting a value in the mode register 604, sending a particular command to the command decoder 606, or activating the timer 608. Activating the validation circuit 122 enables aspects of validation uninitialized usage-based-disturbance data 214 to be performed during the startup procedure 802 and prior to completion of the refresh procedure.

At 806, the validation control circuit 124 determines whether a data-initialization condition is detected. This is a condition that indicates the usage-based-disturbance data 214 has been initialized. This can include the mode register 604 having a particular value, the command decoder 606 receiving a particular command from the memory controller 114, or the timer 608 expiring. If the memory device 108 completes the refresh procedure, for instance, the memory device 108 can set the value of the mode register 604 to indicate that the usage-based-disturbance data 214 has been initialized. If the data-initialized condition is not detected, the process continues at 808.

At 808, the memory device 108 determines whether or not to perform an aspect of usage-based-disturbance mitigation. If the memory device 108 determines to not perform an aspect of usage-based-disturbance mitigation, the validation circuit 122 and the usage-based-disturbance circuitry 120 do nothing, as indicated at 810. Alternatively, if the memory device 108 determines to perform usage-based-disturbance mitigation, the validation circuit 122 performs the validation procedure, as further described at 812. In some implementations, a particular condition or operation can cause the memory device 108 to trigger or activate usage-based-disturbance mitigation. For example, activation of a row 302 within the memory array 204 can trigger activation of the usage-based-disturbance circuitry 120. This row activation can be part of the startup procedure 802 or can be caused by a malicious actor.

At 812, the validation circuit 122 performs a validation procedure to determine whether or not the usage-based-disturbance data 214 is valid. If the validation circuit 122 determines that the usage-based-disturbance data 214 is valid, the usage-based-disturbance circuitry 120 performs usage-based-disturbance mitigation at 814. This can include performing the array counter update procedure.

Alternatively, if the validation circuit 122 determines that the usage-based-disturbance data 214 is invalid, the usage-based-disturbance circuitry 120 initializes the usage-based-disturbance data at 816. The initialization procedure performed by the usage-based-disturbance circuitry 120 can include setting the usage-based-disturbance data 214 to a known state. For example, the usage-based-disturbance circuitry 120 can set a value of the activation count 308 to zero or to a default value (e.g., some fraction of a threshold for triggering a refresh operation). The operation returns to 806.

At some point in time during the startup procedure, the validation control circuit 124 detects the data-initialization condition at 806. This causes the process to continue to 822. At 822, the usage-based-disturbance data 214 is considered to be initialized 616. As such, the validation circuit 122 is deactivated. For example, the validation control circuit 124 causes the validation circuit 122 to be in the inactive state 622.

A time during which the validation circuit 122 is active can vary depending on the implementation. In an example implementation, the validation circuit 122 is active until the memory array 204 is completely refreshed (e.g., all rows 302 of the memory array are refreshed or all rows 302 storing the usage-based-disturbance data 214 are refreshed). This can be approximately 32 or 64 milliseconds in some instances. While the validation circuit 122 is in the inactive state 622, the usage-based-disturbance circuitry 120 operates normally (e.g., operates in accordance with the independent state 628), as described above with respect to FIG. 6.

### Example Method

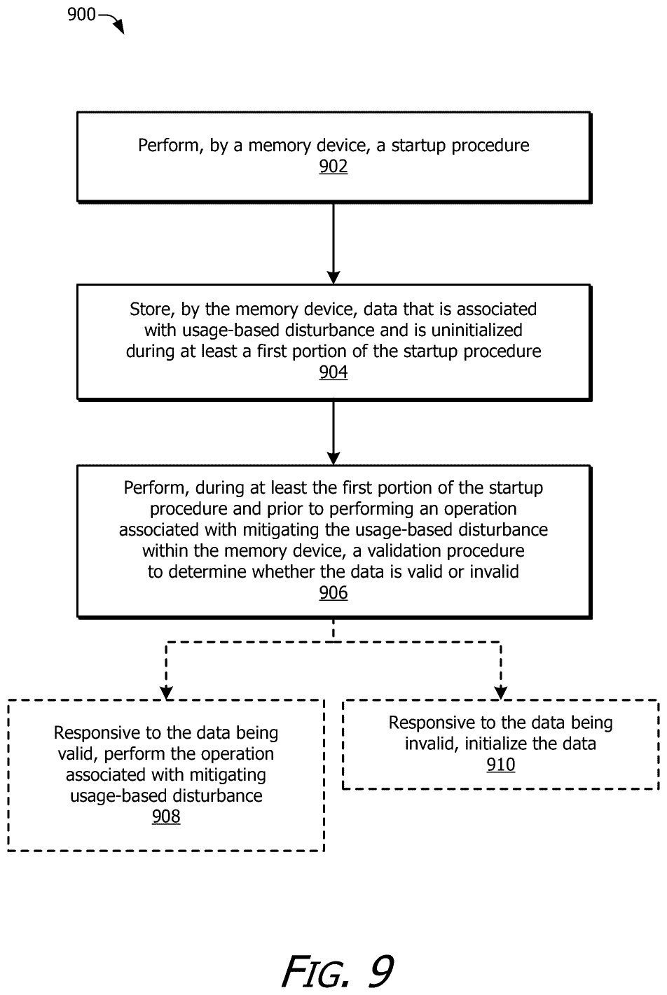

This section describes an example method for implementing aspects of validating uninitialized usage-based-disturbance data with reference to the flow diagram of FIG. 9. These descriptions may also refer to components, entities, and other aspects depicted in FIGS. 1 to 8 by way of example only. The described method is not necessarily limited to performance by one entity or multiple entities operating on one device.

FIG. 9 illustrates a method 900, which includes operations 902 through 910. In aspects, operations of the method 900 are implemented by a memory device 108 as described with reference to FIG. 1. At 902, a startup procedure is performed by a memory device. For example, the memory device 108 performs the startup procedure. The startup procedure can be automatically initiated by the memory device 108 responsive to power being supplied (or re-supplied) to the memory device 108. The startup procedure can include aspects of an initialization procedure, a calibration procedure, a training procedure, a reset procedure, a refresh procedure, or some combination thereof. Generally speaking, the startup procedure represents operations that are performed prior to the memory device 108 being able to perform normal operations (e.g., performing normal read and/or write operations) with the memory controller. During at least a first portion of the startup procedure, the usage-based-disturbance data 214 can be uninitialized 614.

At 904, data that is associated with usage-based disturbance and is uninitialized during at least a first portion of the startup procedure is stored by the memory device. For example, the memory array 204 (or at least one bank 410) stores the usage-based-disturbance data 214. The usage-based-disturbance data 214 is associated with usage-based disturbance in that it is utilized by the usage-based-disturbance circuitry 120 to perform aspects of mitigating usage-based disturbance within the memory device 108. The usage-based-disturbance data 214 is also uninitialized 614 during at least a first portion of the startup procedure.

At 906, a validation procedure is performed to determine whether the data is valid or invalid. The validation procedure is performed during at least the first portion of the startup procedure and prior to performing an operation associated with mitigating the usage-based disturbance within the memory device 108. For example, the validation circuit 122 performs the validation procedure to determine whether the usage-based-disturbance data 214 is valid or invalid. The validation procedure is performed during at least the first portion of the startup procedure and prior to performing an operation associated with mitigating usage-based-disturbance, as shown in FIG. 8. In FIG. 8, the validation procedure is performed at 812, which occurs after the startup procedure is initiated at 802 and prior to 814, which represents the usage-based-disturbance circuitry 120 performing an operation to mitigate usage-based disturbance.

At 908, the operation associated with mitigating usage-based disturbance is performed responsive to the data being valid. For example, responsive to the usage-based-disturbance data 214 being valid, the validation circuit 122 enables the usage-based-disturbance circuitry 120 to perform the operation associated with mitigating usage-based disturbance (e.g., an array counter update procedure). This operation uses the usage-based-disturbance data 214. The operation can at least involve reading the usage-based-disturbance data 214 from the memory array 204.

At 910, the data is initialized responsive to the data being invalid. For example, responsive to the usage-based-disturbance data 214 being invalid, the validation circuit 122 causes the usage-based-disturbance circuitry 120 to initialize the usage-based-disturbance data 214. In this manner, the memory device 108 can incrementally and/or sporadically initialize the usage-based-disturbance data 214 during the startup procedure.

For the figure described above, the order in which operations are shown and/or described are not intended to be construed as a limitation. Any number or combination of the described process operations can be combined or rearranged in any order to implement a given method or an alternative method. Operations may also be omitted from or added to the described methods. Further, described operations can be implemented in fully or partially overlapping manners.

Aspects of this method may be implemented in, for example, hardware (e.g., fixed-circuit circuitry or a processor in conjunction with a memory), firmware, software, or some combination thereof. The method may be realized using one or more of the apparatuses or components shown in FIGS. 1 to 8, the components of which may be further divided, combined, rearranged, and so on. The devices and components of these figures generally represent hardware, such as electronic devices, packaged modules, IC chips, or circuits; firmware or the actions thereof; software; or a combination thereof. Thus, these figures illustrate some of the many possible systems or apparatuses capable of implementing the described methods.

Computer-readable media includes both non-transitory computer storage media and communication media including any medium that facilitates transfer of a computer program (e.g., an application) or data from one entity to another. Non-transitory computer storage media can be any available medium accessible by a computer, such as RAM, ROM, Flash, EEPROM, optical media, and magnetic media.

In the following, various examples for implementing aspects of validation uninitialized usage-based-disturbance data are described:

Example 1: A method performed by a memory device, the method comprising:
performing a startup procedure;
storing data that is associated with usage-based disturbance and is uninitialized during at least a first portion of the startup procedure; and
performing, during at least the first portion of the startup procedure and prior to performing an operation associated with mitigating the usage-based disturbance within the memory device, a validation procedure to determine whether the data is valid or invalid.

Example 2: The method of example 1 or any other example, further comprising:
responsive to determining that the data is valid, performing the operation associated with mitigating the usage-based disturbance, the operation using the data; or
responsive to determining that the data is invalid, initializing the data.

Example 3: The method of example 2 or any other example, wherein performing the operation comprises reading the data from the memory device, updating the data, and writing the updated data to the memory device.

Example 4: The method of example 1 or any other example, wherein performing the validation procedure comprises performing the validation procedure responsive to a row of the memory device being activated during the first portion of the startup procedure.

Example 5: The method of example 1 or any other example, wherein performing the validation procedure comprises at least one of the following:
evaluating a parity of the data; or
evaluating a value of the data.

Example 6: The method of example 5 or any other example, wherein:
the data comprises a parity bit and other data; and
evaluating the parity of the data comprises:
   validating the data responsive to the parity bit representing a parity of the other data; or
   invalidating the data responsive to the parity bit not representing the parity of the other data.

Example 7: The method of example 5 or any other example, wherein:
the data comprises an activation count; and
evaluating the value of the data comprises:
   validating the data responsive to the activation count being less than a threshold; or
   invalidating the data responsive to the activation count being greater than the threshold.

Example 8: The method of example 5 or any other example, wherein:
the data comprises an activation count; and
evaluating the value of the data comprises:
   counting a total quantity of activations since a beginning of the startup procedure to generate a total activation count;
   validating the data responsive to the activation count being less than the total activation count; and
   invalidating the data responsive to the activation count being greater than the total activation count.

Example 9: The method of example 1 or any other example, further comprising:
disabling, during a second portion of the startup procedure, the validation procedure; and
enabling the operation associated with mitigating usage-based disturbance to be performed without the validation procedure.

Example 10: The method of example 9 or any other example, further comprising:
detecting, during the second portion of the startup procedure, a condition indicative of the data having been initialized,
wherein disabling the validation procedure comprises disabling the validation procedure responsive to the detecting of the condition.

Example 11: The method of example 10 or any other example, wherein detecting the condition comprises at least one of the following:
determining that a mode register of the memory device has an operand with a certain value;
receiving a command from a memory controller that is coupled to the memory device; or
detecting an expiration of a timer.

Example 12: The method of example 11 or any other example, wherein:
detecting the condition comprises at least the determining that the mode register has the operand with the certain value; and
the method further comprises:
   performing, by the memory device and during the second portion of the startup procedure, a refresh procedure that initializes the data; and
   setting, by the memory device, a value of the operand of the mode register to indicate completion of the refresh procedure.

Example 13: An apparatus comprising:
a memory device configured to perform a startup procedure, the memory device comprising:
   at least one bank comprising multiple rows of memory cells, each row of the multiple rows configured to store, within a subset of the memory cells, data associated with usage-based disturbance, the data being uninitialized during at least a first portion of the startup procedure; and
   at least one circuit configured to perform, during at least the first portion of the startup procedure and prior to the memory device performing an operation associated with mitigating the usage-based disturbance, a validation procedure to determine whether the data is valid or invalid.

Example 14: The apparatus of example 13 or any other example, wherein:
the memory device comprises at least one second circuit configured to perform the operation associated with mitigating usage-based disturbance within the at least one bank; and
the circuit is configured to selectively:
   cause the second circuit to perform the operation responsive to a determination that the data is valid; or
   cause the second circuit to initialize the data responsive to a determination that the data is invalid.

Example 15: The apparatus of example 13 or any other example, wherein:
the data comprises a parity bit; and
the circuit comprises a parity checker configured to determine whether the data is valid or invalid based on the parity bit.

Example 16: The apparatus of example 13 or any other example, wherein:
the data comprises an activation count; and
the circuit comprises a sensibility checker configured to determine whether the data is valid or invalid based on a comparison of the activation count to another value.

Example 17: The apparatus of example 16 or any other example, wherein the other value comprises:
a total quantity of activations since a beginning of the startup procedure; or
a threshold.

Example 18: A method performed by a memory device, the method comprising:
performing a startup procedure;
storing data that is associated with usage-based disturbance and is uninitialized during at least a first portion of the startup procedure;
determining, during the first portion of the startup procedure, that at least a portion of the data is invalid; and
initializing the portion of the data based on the determining.

Example 19: The method of example 18 or any other example, further comprising:
determining, during the first portion of the startup procedure, that at least another portion of the data is valid; and
performing, during the first portion of the startup procedure, an operation associated with mitigating usage-based disturbance based on the determining that the other portion of the data is valid, the operation utilizing the other portion of the data.

Example 20: The method of example 18 or any other example, further comprising:
completing initialization of the data during a second portion of the startup procedure; and
performing, after completing the initialization, the operation associated with mitigating usage-based disturbance without validating the data.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

### CONCLUSION

Although aspects of validating uninitialized usage-based-disturbance data have been described in language specific to certain features and/or methods, the subject of the appended claims is not necessarily limited to the specific features or methods described. Rather, the specific features and methods are disclosed as a variety of example implementations of validating uninitialized usage-based-disturbance data.

What is claimed is:

1. A method performed by a memory device, the method comprising:
performing a startup procedure;
storing data that is associated with usage-based disturbance and is uninitialized during at least a first portion of the startup procedure; and
performing, during at least the first portion of the startup procedure and prior to performing an operation associated with mitigating the usage-based disturbance within the memory device, a validation procedure to determine whether the data is valid or invalid.

2. The method of claim 1, further comprising:
responsive to determining that the data is valid, performing the operation associated with mitigating the usage-based disturbance, the operation using the data; or
responsive to determining that the data is invalid, initializing the data.

3. The method of claim 2, wherein performing the operation comprises reading the data from the memory device, updating the data, and writing the updated data to the memory device.

4. The method of claim 1, wherein performing the validation procedure comprises performing the validation procedure responsive to a row of the memory device being activated during the first portion of the startup procedure.

5. The method of claim 1, wherein performing the validation procedure comprises at least one of the following:
evaluating a parity of the data; or
evaluating a value of the data.

6. The method of claim 5, wherein:
the data comprises a parity bit and other data; and
evaluating the parity of the data comprises:
validating the data responsive to the parity bit representing a parity of the other data; or
invalidating the data responsive to the parity bit not representing the parity of the other data.

7. The method of claim 5, wherein:
the data comprises an activation count; and
evaluating the value of the data comprises:
validating the data responsive to the activation count being less than a threshold; or
invalidating the data responsive to the activation count being greater than the threshold.

8. The method of claim 5, wherein:
the data comprises an activation count; and
evaluating the value of the data comprises:
counting a total quantity of activations since a beginning of the startup procedure to generate a total activation count;
validating the data responsive to the activation count being less than the total activation count; and
invalidating the data responsive to the activation count being greater than the total activation count.

9. The method of claim 1, further comprising:
disabling, during a second portion of the startup procedure, the validation procedure; and
enabling the operation associated with mitigating the usage-based disturbance to be performed without the validation procedure.

10. The method of claim 9, further comprising:
detecting, during the second portion of the startup procedure, a condition indicative of the data having been initialized,
wherein disabling the validation procedure comprises disabling the validation procedure responsive to detecting the condition.

11. The method of claim 10, wherein detecting the condition comprises at least one of the following:
determining that a mode register of the memory device has an operand with a certain value;
receiving a command from a memory controller that is coupled to the memory device; or
detecting an expiration of a timer.

12. The method of claim 11, wherein:
detecting the condition comprises at least the determining that the mode register has the operand with the certain value; and
the method further comprises:
performing, by the memory device and during the second portion of the startup procedure, a refresh procedure that initializes the data; and
setting, by the memory device, a value of the operand of the mode register to indicate completion of the refresh procedure.

13. An apparatus comprising:
a memory device configured to perform a startup procedure, the memory device comprising:
at least one bank comprising multiple rows of memory cells, each row of the multiple rows configured to store, within a subset of the memory cells, data associated with usage-based disturbance, the data being uninitialized during at least a first portion of the startup procedure; and
at least one circuit configured to perform, during at least the first portion of the startup procedure and prior to the memory device performing an operation associated with mitigating the usage-based disturbance, a validation procedure to determine whether the data is valid or invalid.

14. The apparatus of claim 13, wherein:
the memory device comprises at least one second circuit configured to perform the operation associated with mitigating the usage-based disturbance within the at least one bank; and
the circuit is configured to selectively:
cause the second circuit to perform the operation responsive to a determination that the data is valid; or
cause the second circuit to initialize the data responsive to a determination that the data is invalid.

15. The apparatus of claim 13, wherein:
the data comprises a parity bit; and
the circuit comprises a parity checker configured to determine whether the data is valid or invalid based on the parity bit.

16. The apparatus of claim 13, wherein:
the data comprises an activation count; and
the circuit comprises a sensibility checker configured to determine whether the data is valid or invalid based on a comparison of the activation count to another value.

17. The apparatus of claim 16, wherein the other value comprises:
a total quantity of activations since a beginning of the startup procedure; or
a threshold.

18. A method performed by a memory device, the method comprising:
performing a startup procedure;
storing data that is associated with usage-based disturbance and is uninitialized during at least a first portion of the startup procedure;
determining, during the first portion of the startup procedure, that at least a portion of the data is invalid; and
initializing the portion of the data based on the determining.

19. The method of claim 18, further comprising:
determining, during the first portion of the startup procedure, that at least another portion of the data is valid; and
performing, during the first portion of the startup procedure, an operation associated with mitigating the usage-based disturbance based on the determination that the other portion of the data is valid, the operation utilizing the other portion of the data.

20. The method of claim 18, further comprising:
completing initialization of the data during a second portion of the startup procedure; and
performing, after completing the initialization, the operation associated with mitigating the usage-based disturbance without validating the data.
